(19) United States
(12) Patent Application Publication
(10) Pub. No.: US 2011/0162684 A1
(43) Pub. Date: Jul. 7, 2011

(54) METHOD FOR MANUFACTURING THIN FILM TYPE SOLAR CELL, AND THIN FILM TYPE SOLAR CELL MADE BY THE METHOD

(75) Inventors: Jae Ho Kim, Gyeonggi-do (KR); Jin Hong, Gyeonggi-do (KR); Chang-Sil Yang, Gyeonggi-do (KR)

(73) Assignee: JUSUNG ENGINEERING CO., LTD., Gyeonggi-do (KR)

(21) Appl. No.: 12/672,494

(22) PCT Filed: Aug. 6, 2008
(86) PCT No.: PCT/KR08/04573

§ 371 Date: Feb. 5, 2010

(30) Foreign Application Priority Data
Aug. 6, 2007 (KR) 10-2007-0078405

(51) Int. Cl. H01L 31/05; H01L 31/18

(52) U.S. Cl. 136/244; 438/68; 257/E31.061

(57) ABSTRACT

A method for manufacturing a thin film type solar cell and a thin film type solar cell manufactured by the method is disclosed. The method is comprised of a first process for forming a plurality of unit front electrode patterns at predetermined intervals on a substrate; a second process for forming a semiconductor layer pattern on the substrate, wherein the semiconductor layer pattern is comprised of a separating part to divide the solar cell into unit cells, and a contact part to connect the electrode patterns electrically; and a third process for forming a plurality of unit rear electrode patterns which are respectively connected with the unit front electrode patterns through the contact part, and are separated from one another by the separating part.

### TECHNICAL FIELD

The present invention relates to a thin film type solar cell, and more particularly, to a thin film type solar cell with a plurality of unit cells connected in series.

### BACKGROUND ART

A solar cell with a property of semiconductor converts a light energy into an electric energy.

A structure and principle of the solar cell according to the related art will be briefly explained as follows.

The solar cell is formed in a PN-junction structure where a positive(P)-type semiconductor makes a junction with a negative(N)-type semiconductor.

When a solar ray is incident on the solar cell of the PN-junction structure, holes(+) and electrons(−) are generated in the semiconductor owing to the energy of the solar ray. By an electric field generated in an PN-junction area, the holes(+) are drifted toward the P-type semiconductor, and the electrons(−) are drifted toward the N-type semiconductor, whereby an electric power is produced with an occurrence of electric potential.

The solar cell is largely classified into a wafer type solar cell and a thin film type solar cell.

The wafer type solar cell uses a wafer made of a semiconductor material such as silicon. In the meantime, the thin film type solar cell is manufactured by forming a semiconductor in type of a thin film on a glass substrate.

In the efficiency respect, the wafer type solar cell is better than the thin film type solar cell. However, in the case of the wafer type solar cell, it is difficult to realize a small thickness due to a difficult in performing the process. In addition, the wafer type solar cell uses a high-priced semiconductor wafer, whereby its manufacturing cost is increased.

Even though the thin film type solar cell is inferior in efficiency to the wafer type solar cell, the thin film type solar cell has advantages such as realization of thin profile and use of low-priced material. Accordingly, the thin film type solar cell is suitable for a mass production.

The thin film type solar cell is manufactured by sequential steps of forming a front electrode on a glass substrate, forming a semiconductor layer on the front electrode, and forming a rear electrode on the semiconductor layer. In this case, since the front electrode corresponds to a light-incidence face, the front electrode is made of a transparent conductive material, for example, ZnO. With the large-sized substrate, a power loss increases due to a resistance of the transparent conductive layer.

Thus, a method for minimizing the power loss has been proposed, in which the thin film type solar cell is divided into a plurality of unit cells, and the plurality of unit cells are connected in series. This method enables the minimization of power loss caused by the resistance of the transparent conductive material.

Hereinafter, a related art method for manufacturing a thin film type solar cell with a plurality of unit cells connected in series will be described with reference to FIGS. 1A to 1G.

First, as shown in FIG. 1A, a front electrode layer 12 is formed on a substrate 10, wherein the front electrode layer 12 is made of a transparent conductive material, for example, ZnO.

As shown in FIG. 1B, the front electrode layer 12 is patterned by a laser-scribing method, to thereby form unit front electrodes 12a, 12b, and 12c.

As shown in FIG. 1C, a semiconductor layer 14 is formed on an entire surface of the substrate 10. The semiconductor layer 14 is made of a semiconductor material, for example, silicon. The semiconductor layer 14 is formed in a PIN structure sequentially depositing a P-type semiconductor layer, an intrinsic semiconductor layer, and an N-type semiconductor layer.

As shown in FIG. 1D, the semiconductor layer 14 is patterned by a laser-scribing method, to thereby form unit semiconductor layers 14a, 14b, and 14c.

As shown in FIG. 1E, a transparent conductive layer 16 and a metal layer 18 are sequentially formed on the entire surface of the substrate 10; thereby forming a rear electrode layer 20. The transparent conductive layer 16 is made of ZnO, and the metal layer 18 is made of Al.

As shown in FIG. 1F, unit rear electrodes 20a, 20b, and 20c are formed by patterning the rear electrode layer 20. When patterning the rear electrode layer 20, the unit semiconductor layers 14b and 14c positioned under the rear electrode layer 20 are patterned together with the rear electrode layer 20 by a laser-scribing method.

As shown in FIG. 1G, the outermost portions of the substrate 10 are isolated by patterning the outermost unit rear electrodes 20a and 20c, the outermost unit semiconductor layers 14a and 14c, and the outermost unit front electrodes 12a and 12c. This is because that a short may occur when connecting the complete thin film type solar cell with housing as one module. The isolation of the outermost portions of the substrate 10 enables the prevention of short between the thin film type solar cell and the housing.

Patterning the outermost portions of the substrate 10 is performed by a laser-scribing method. The outermost portions of the substrate 10 are comprised of different material layers. Thus, the unit rear electrodes 20a and 20c, and the unit semiconductor layers 14a and 14c are firstly scribed by laser of a relatively small wavelength, and then the unit front electrodes 12a and 12c are secondly scribed by laser of a relatively large wavelength.

However, the related art method for manufacturing the thin film type solar cell has the following disadvantages.

First, the related art method is complicated due to the four patterning steps, that is, the patterning step (See FIG. 1B) for the front electrode layer 12, the patterning step (See FIG. 1D) for the semiconductor layer 14, the patterning step (See FIG. 1F) for the rear electrode layer 20, and the patterning step (See FIG. 1G) for the outermost portions of the substrate 10.

Second, the four patterning steps are performed by the laser-scribing method. During the laser-scribing method, the remnant that remains in the substrate may contaminate the substrate. In this respect, a cleaning process is additionally performed so as to prevent the contamination of the substrate. However, the additional cleaning process may cause complicacy and low yield.

### DISCLOSURE

### Technical Problem

Therefore, the present invention has been made in view of the above problems, and it is an object of the present invention to provide a method for manufacturing a thin film type solar cell with a simplified process by reducing patterning steps, and a thin film type solar cell manufactured by the method.

It is another object of the present invention to provide a method for manufacturing a thin film type solar cell, which is capable of reducing a contamination possibility of substrate by decreasing the number of laser-scribing processes during a patterning step, and is capable of improving the yield by omitting a cleaning process.

### Technical Solution

To achieve these objects and other advantages and in accordance with the purpose of the invention, as embodied and broadly described herein, a method for manufacturing a thin film type solar cell comprises a first process for forming a plurality of unit front electrode patterns at predetermined intervals on a substrate; a second process for forming a semiconductor layer pattern on the substrate, wherein the semiconductor layer pattern is comprised of a separating part to divide the solar cell into unit cells, and a contact part to connect the electrode patterns electrically; and a third process for forming a plurality of unit rear electrode patterns which are respectively connected with the unit front electrode patterns through the contact part, and are separated from one another by the separating part.

At this time, the first process comprises forming a first isolating part in the outermost unit front electrode pattern in order to isolate the outermost portions of the substrate by the first isolating part.

The first process comprises forming a front electrode layer on the substrate; and patterning the front electrode layer.

The first process comprises forming the front electrode patterns on the substrate by a screen printing method, an inkjet printing method, a gravure printing method, or a micro-contact printing method.

The first process additionally comprises a texturing process performed to the surface of front electrode patterns.

The second process comprises forming a semiconductor layer on an entire surface of the substrate; and patterning the semiconductor layer.

The second process comprises sequentially forming a semiconductor layer and a transparent conductive layer on an entire surface of the substrate; and patterning the semiconductor layer and the transparent conductive layer.

The second process comprises forming a second isolating part in the outermost semiconductor layer pattern, in order to isolate the outermost portions of the substrate by the first and second isolating parts, wherein the second isolating part corresponds to the first isolating part of the front electrode pattern.

The second process comprises forming the semiconductor layer pattern of PIN structure where a P-type semiconductor layer, an intrinsic semiconductor layer, and an N-type semiconductor layer are deposited in sequence.

The third process comprises forming the rear electrode pattern by a screen printing method, an inkjet printing method, a gravure printing method, or a micro-contact printing method.

The third process comprises forming a third isolating part in the outermost rear electrode pattern, in order to isolate the outermost portions of the substrate by the first, second, and third isolating parts, wherein the third isolating part corresponds to the first isolating part of the front electrode pattern.

In another aspect of the present invention, a method for manufacturing a thin film solar cell comprises forming a front electrode layer on an entire surface of substrate; forming a plurality of unit front electrode patterns at predetermined intervals by patterning the front electrode layer, wherein the outermost front electrode pattern is provided with a first isolating part; forming a semiconductor layer and a transparent conductive layer on the entire surface of substrate, sequentially; patterning the semiconductor layer and the transparent conductive layer, so as to form a separating part to divide the solar cell into unit cells, a contact part to electrically connect the electrode patterns, and a second isolating part corresponding to the first isolating part of the front electrode pattern; and forming a plurality of unit rear electrode patterns which are provided with a third isolating part corresponding to the first isolating part of the front electrode pattern, are respectively connected with the unit front electrode patterns through the contact part, and are separated from one another by the separating part.

At this time, forming the unit rear electrode pattern is performed by a screen printing method, an inkjet printing method, a gravure printing method, or a micro-contact printing method.

In another aspect of the present invention, a thin film type solar cell comprises a plurality of unit front electrode patterns at predetermined intervals on a substrate; a semiconductor layer pattern on the substrate, wherein the semiconductor layer pattern is provided with a separating part to divide the solar cell into unit cells, and a contact part to electrically connect the electrode patterns; a transparent conductive layer pattern above the semiconductor layer pattern, wherein the transparent conductive layer pattern is formed in the same pattern as the semiconductor layer pattern; and a plurality of unit rear electrode patterns which are respectively connected with the unit front electrode patterns through the contact part, and are separated from one another by the separating part.

At this time, a first isolating part is formed in the outermost unit front electrode pattern.

Also, the semiconductor layer pattern includes a second isolating part formed at a portion corresponding to the first isolating part of the front electrode pattern, in which the second isolating part is formed by removing the semiconductor layer; and the rear electrode pattern includes a third isolating part formed at a portion corresponding to the first isolating part of the front electrode pattern, in which the third isolating part is formed by removing the rear electrode.

The plurality of unit front electrode patterns are provided with the uneven surfaces.

The semiconductor layer pattern is formed in a PIN structure where a P-type semiconductor layer, an intrinsic semiconductor layer, and an N-type semiconductor layer are deposited in sequence.

### Advantageous Effects

Accordingly, the method for manufacturing the thin film type solar cell according to the present invention and the thin film type solar cell manufactured by the method have the following advantages.

First, the thin film type solar cell according to the present invention is manufactured by the total three patterning steps, that is, the patterning step for the unit front electrode, the patterning step for the semiconductor layer, and the patterning step for the unit rear electrode, whereby the manufacturing method of the thin film type solar cell according to the present invention becomes simpler than the related art method.

Especially, it is necessary for the related art method to perform the step for patterning the outermost portions of the substrate. However, in the case of the method for manufacturing the thin film type solar cell according to the present invention, the outermost portions of the substrate are patterned when performing the three patterning steps aforementioned. That is, since the first, second, and third isolating parts are formed during the three patterning steps aforementioned, there is no requirement for the additional step for patterning the outermost portions of the substrate.

Second, the method for manufacturing the thin film type solar cell according to the present invention can minimize the use of laser-scribing method, so that it is possible to reduce the possibility of the substrate's contamination by remnants generated for the laser-scribing, and a additional cleaning step for removing the remnants.

In the method for manufacturing the thin film type solar cell according to the present invention, the step for patterning the unit rear electrode may be performed by a screen printing method, an inkjet printing method, a gravure printing method, or a micro-contact printing method, instead of the laser-scribing method, thus, it can reduce the use of laser-scribing. Also, if the steps for patterning the unit front electrode as well as the unit rear electrode are performed by the screen printing method, the inkjet printing method, the gravure printing method, or the micro-contact printing method, it can reduce the use of laser-scribing two times.

### DESCRIPTION OF DRAWINGS

FIGS. 1A to 1G are cross section views illustrating a method for manufacturing a thin film type solar cell with a plurality of unit cells connected in series according to a related art;

FIGS. 2A to 2F are cross section views illustrating a method for manufacturing a thin film type solar cell according to one embodiment of the present invention; and

FIG. 3 is a cross section view illustrating a thin film type solar cell according to one embodiment of the present invention.

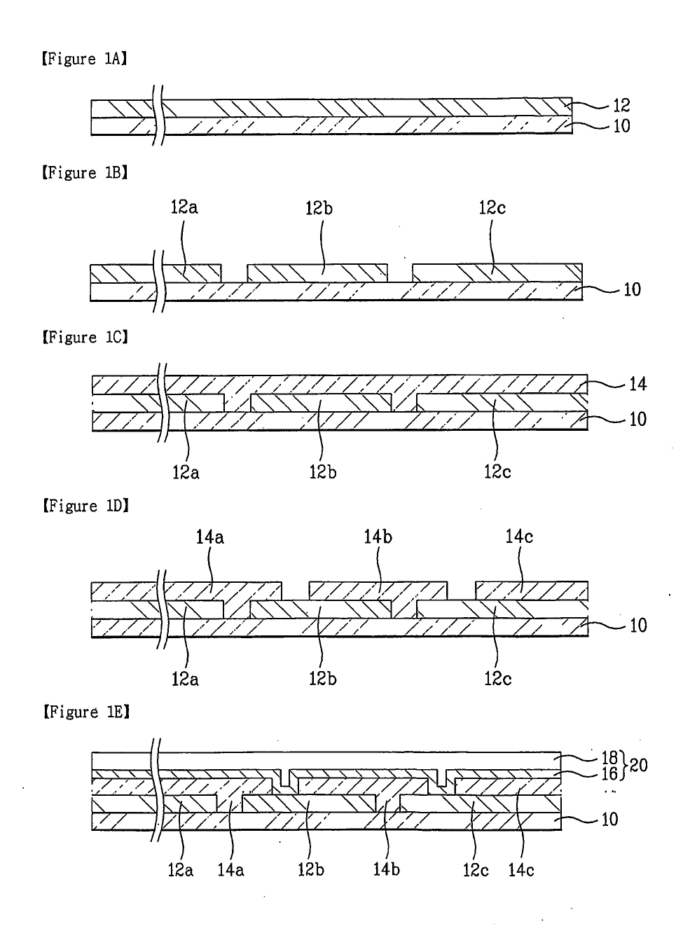

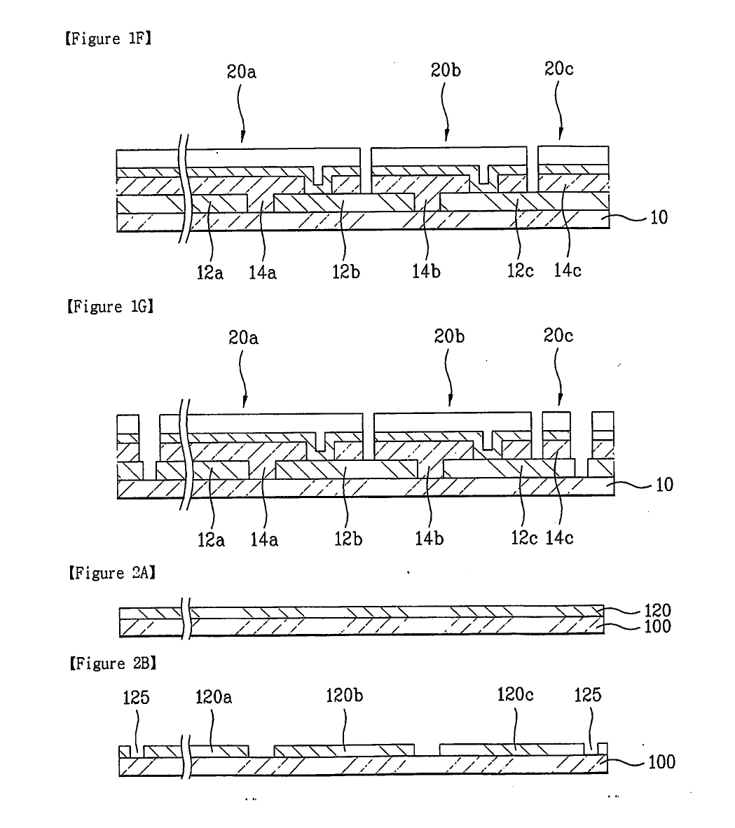

### BEST MODE

Reference will now be made in detail to the preferred embodiments of the present invention, examples of which are illustrated in the accompanying drawings. Wherever possible, the same reference numbers will be used throughout the drawings to refer to the same or like parts.

Hereinafter, a method for manufacturing a thin film type solar cell according to one embodiment of the present invention and a thin film type solar cell manufactured by the same method will be described with reference to the accompanying drawings.

### <Method for Manufacturing Thin Film Type Solar Cell>

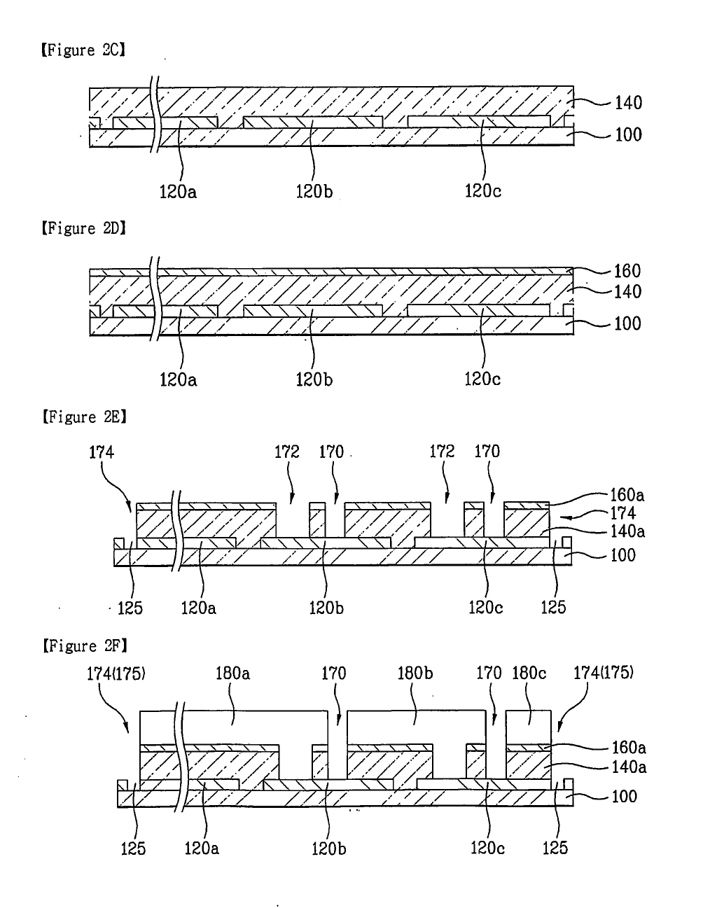

FIGS. 2A to 2F are cross section views illustrating a method for manufacturing a thin film type solar cell according to one embodiment of the present invention.

As shown in FIG. 2A, a front electrode layer 120 is formed on a substrate 100. The substrate 100 may be made of glass or transparent plastic. The front electrode layer 120 is formed of a transparent conductive material, for example, ZnO, ZnO:B, ZnO:Al, SnO₂, SnO₂:F, or ITO (Indium Tin Oxide) by sputtering or MOCVD (Metal Organic Chemical Vapor Deposition).

The front electrode layer 120 corresponds to a solar-ray incidence face. In this respect, it is important for the front electrode layer 120 to transmit the solar ray into the inside of the solar cell with the minimized loss. For this, a texturing process may be additionally performed to the front electrode layer 120.

Through the texturing process, a surface of material layer is provided with an uneven surface, that is, a texture structure, by an etching process using photolithography, an anisotropic etching process using a chemical solution, or a mechanical scribing process. According as the texturing process is performed to the front electrode layer 120, a solar-ray reflection ratio on the front electrode layer 120 of the solar cell is decreased and a solar-ray absorbing ratio in the solar cell is increased owing to a dispersion of the solar ray, thereby improving the efficiency of solar cell.

As shown in FIG. 2B, the front electrode layer 120 is patterned. By patterning the front electrode layer 120, a plurality of unit front electrode patterns 120a, 120b, and 120c are formed at predetermined intervals. Also, a first isolating part 125 is formed in the outermost unit front electrode patterns 120a and 120c. When the complete thin film type solar cell is connected with a predetermined housing as one module, the first isolating part 125 prevents a short from occurring between the housing and the thin film type solar cell. That is, the outermost portion of the substrate 100 is isolated by the first isolating part 125.

The front electrode layer 120 is patterned by a laser-scribing method.

The unit front electrode patterns 120a, 120b, and 120c may be directly formed by performing a screen printing method, an inkjet printing method, a gravure printing method, or a micro-contact printing method, instead of performing the laser-scribing method to the front electrode layer 120 formed on the entire surface of the substrate 100.

In the case of the screen printing method, a material is transferred to a predetermined body through the use of a screen and a squeeze. The inkjet printing method sprays a material onto a predetermined body through the use of an inkjet, to thereby form a predetermined pattern thereon. In the case of the gravure printing method, a material is coated on an intaglio plate, and then the coated material is transferred to a predetermined body, thereby forming a predetermined pattern on the predetermined body. The micro-contact printing method forms a predetermined pattern of material on a predetermined body through the use of a predetermined mold.

If forming the unit front electrode patterns 120a, 120b, and 120c by the screen printing method, the inkjet printing method, the gravure printing method, or the micro-contact printing method, there is less worry about the contamination of substrate, in comparison to the laser-scribing method. Furthermore, in the case of the screen printing method, the inkjet printing method, the gravure printing method, or the micro-contact printing method, it is not required to carry out a cleaning process for preventing the contamination of the substrate.

After forming the front electrode layer 120 on the entire surface of the substrate 100, the unit front electrode patterns 120a, 120b, and 120c may be formed by photolithography.

Next, as shown in FIG. 2C, a semiconductor layer 140 is formed on the entire surface of the substrate 100. The semiconductor layer 140 is formed on the space between each of the unit front electrode patterns 120a, 120b, and 120c, the inner space of the first isolating part 125, and the upper space of the unit front electrode patterns 120a, 120b, and 120c.

The semiconductor layer 140 may be formed of a silicon-based, CuInSe₂-based, or CdTe-based semiconductor material by a plasma-CVD method. The silicon-based semiconductor material may be formed of amorphous silicon (a-Si:H) or microcrystalline silicon (μ c-Si:H).

The semiconductor layer 140 may be formed in a PIN structure where a P-type semiconductor layer, an intrinsic semiconductor layer, and an N-type semiconductor layer are deposited in sequence. At this time, holes and electrons are generated in the semiconductor layer 140 by solar rays, and the generated holes and electros are collected in the P-type semiconductor layer and the N-type semiconductor layer, respectively. For improvement of the efficiency in collection of the holes and electrons, the PIN structure is more preferable than a PN structure comprised of the P-type semiconductor layer and the N-type semiconductor layer.

If the semiconductor layer 140 is formed in the PIN structure, depletion occurs in the intrinsic semiconductor layer by the P-type semiconductor layer and the N-type semiconductor layer. Thus, an electric field is generated inside the PIN structure, whereby the holes and electrons generated by the solar ray are drifted by the electric field. As a result, the holes and electrons are collected in the P-type semiconductor layer and the N-type semiconductor layer, respectively.

When forming the semiconductor layer 140 of the PIN structure, preferably, the P-type semiconductor layer is formed on the unit front electrode patterns 120a, 120b, and 120c, and then the intrinsic semiconductor layer and the N-type semiconductor layer are formed thereon in sequence. This is because a drift mobility of the hole is less than a drift mobility of the electron. In order to maximize the collection efficiency by the incident light, the P-type semiconductor layer is formed adjacent to the light-incidence face.

As shown in FIG. 2D, a transparent conductive layer 160 is formed on the semiconductor layer 140.

The transparent conductive layer 160 is formed of a transparent conductive material, for example, ZnO, ZnO:B, ZnO:Al, or Ag by sputtering or MOCVD (Metal Organic Chemical Vapor Deposition).

The process of forming the transparent conductive layer 160 may be omitted. To improve the efficiency of the solar cell, the transparent conductive layer 160 is formed, preferably. That is, if forming the transparent conductive layer 160, the solar ray passes through the semiconductor layer 140, and then passes through the transparent conductive layer 160. In this case, the solar ray passing through the transparent conductive layer 160 is dispersed at different angles. As a result, the solar ray is reflected on rear electrode patterns 180a, 180b, and 180c (See. FIG. 2F), thereby increasing re-incidence of the solar ray on the semiconductor layer 140.

As shown in FIG. 2E, the semiconductor layer 140 and the transparent conductive layer 160 are patterned at the same time, thereby forming a semiconductor layer pattern 140a and a transparent conductive layer pattern 160a. At this time, a separating part 170, a contact part 172, and a second isolating part 174 are formed by patterning the semiconductor layer 140 and the transparent conductive layer 160.

The separating part 170 divides the solar cell into unit cells. The contact part 172 electrically connects the unit front electrode pattern 120b and 120c with the unit rear electrode pattern 180a and 180b (See FIG. 2F), respectively. The second isolating part 174 corresponds to the first isolating part 125 mentioned above. The second isolating part 174 is formed by removing the outermost portions of the semiconductor layer 140 and the transparent conductive layer 160. Accordingly, the outermost portions of the substrate 100 are isolated by the first and second isolating parts 125 and 174.

The semiconductor layer 140 and the transparent conductive layer 160 may be patterned by a laser-scribing method, but it is not limited to this. The semiconductor layer 140 and the transparent conductive layer 160 may be patterned by photolithography.

As shown in FIG. 2F, the plurality of unit rear electrode patterns 180a, 180b, and 180c are formed with the separating part 170 interposed therebetween. That is, the separating part 170 is formed between each of the unit rear electrode patterns 180a, 180b, and 180c.

The plurality of unit rear electrode patterns 180a and 180b are respectively connected with the unit front electrode patterns 120b and 120c through the contact part 172. Also, a third isolating part 175 is formed in the outermost unit rear electrode patterns 180a and 180c. The third isolating part 175 corresponds to the first isolating part 125 mentioned above, and the third isolating part 175 is provided at the same position as the second isolating part 174. Accordingly, the outermost portions of the substrate 100 are isolated by the first isolating part 125, the second isolating part 174, and the third isolating part 175.

The outermost portions of the thin film type solar cell are separated by the first isolating part 125 of the unit front electrode 120a and 120c, the second isolating part 174 of the semiconductor layer 140 and the transparent conductive layer 160, and the third isolating part 175 of the unit rear electrode 180a and 180c, so that it is possible to prevent the short from occurring between the housing and the thin film type solar cell during the module process. Especially, since the first isolating part 125, and the second isolating part 174, and the third isolating part 175 are formed when patterning the front electrode layer 120, the semiconductor layer 140, the transparent conductive layer 160, and the rear electrode layer 180, there is no requirement for the additional process of separating the outermost portions of the thin film type solar cell.

The unit rear electrode patterns 180a, 180b, and 180c may be formed of a metal material such as Ag, Al, Ag+Mo, Ag+Ni, or Ag+Cu by the screen printing method, the inkjet printing method, the gravure printing method, or the micro-contact printing method.

### <Thin Film Type Solar Cell>

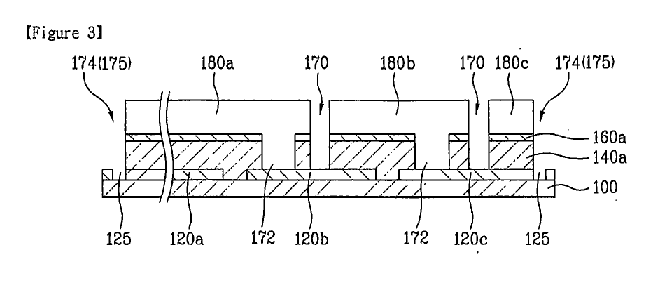

FIG. 3 is a cross section view illustrating a thin film type solar cell according to one embodiment of the present invention.

As shown in FIG. 3, a thin film type solar cell according to one embodiment of the present invention includes a substrate 100; a plurality of unit front electrode patterns 120a, 120b, and 120c; a semiconductor layer pattern 140a; a transparent conductive layer pattern 160a; and a plurality of unit rear electrode patterns 180a, 180b, and 180c.

The substrate 100 may be made of glass or transparent plastic.

The plurality of unit front electrode patterns 120a, 120b, and 120c may be formed of a transparent conductive material, for example, ZnO, ZnO:B, ZnO:Al, SnO₂, SnO₂:F, or ITO (Indium Tin Oxide).

The plurality of unit front electrode patterns 120a, 120b, and 120c are formed at predetermined intervals on the substrate 100. Also, a first isolating part 125 is formed in the outermost unit front electrode patterns 120a and 120c among the plurality of unit front electrode patterns 120a, 120b, and 120c.

According as a texturing process is performed, surfaces of the plurality of unit front electrode patterns 120a, 120b, and 120c become uneven, whereby the plurality of unit front electrode patterns 120a, 120b, and 120c have a texture structure on their surfaces.

The semiconductor layer pattern 140a may be formed of a silicon-based, CuInSe₂-based, or CdTe-based semiconductor material. Also, the semiconductor layer pattern 140a may be formed in a PIN structure where a P-type semiconductor layer, an intrinsic semiconductor layer, and an N-type semiconductor layer are deposited in sequence.

The semiconductor layer pattern 140 is provided with a separating part 170 to divide the solar cell into unit cells; and a contact part 172 to connect the electrodes electrically. In the outermost portions of the semiconductor layer pattern 140a, there is a second isolating part 174 which corresponds to the first isolating part 125 of the unit front electrode patterns 120a and 120c.

The transparent conductive layer pattern 160a may be formed of a transparent conductive material such as ZnO, ZnO:B, ZnO:Al, or Ag.

The transparent conductive layer pattern 160a is formed above the semiconductor layer pattern 140a, wherein the transparent conductive layer pattern 160a and the semiconductor layer pattern 140a are formed in the same pattern. That is, the transparent conductive layer pattern 160a is provided with a separating part 170 and a contact part 172. In the outermost portions of the transparent conductive layer pattern 160a, there is a second isolating part 174.

The plurality of unit rear electrode patterns 180a, 180b, and 180c are separated from one another by the separating part 170. Through the contact part 172, the unit rear electrode patterns 180a and 180b are respectively connected with the unit front electrode patterns 120b and 120c. In the outermost unit rear electrode patterns 180a and 180c, there is a third isolating part 175 corresponding to the first isolating part 125 of the front electrode. The third isolating part 175 is formed in the same position as the second isolating part 174.

The thin film type solar cell according to one embodiment of the present invention can be manufactured by the method of FIGS. 2A to 2F.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

1. A method for manufacturing a thin film type solar cell comprising:
a first process, for forming a plurality of unit front electrode patterns at predetermined intervals on a substrate;
a second process for forming a semiconductor layer pattern on the substrate, wherein the semiconductor layer pattern is comprised of a separating part to divide the solar cell into unit cells, and a contact part to connect the electrode patterns electrically; and
a third process for forming a plurality of unit rear electrode patterns which are respectively connected with the unit front electrode patterns through the contact part, and are separated from one another by the separating part.

2. The method according to claim 1, wherein the first process comprises:
forming a first isolating part in the outermost unit front electrode pattern in order to isolate the outermost portions of the substrate by the first isolating part.

3. The method according to claim 1, wherein the first process comprises:
forming a front electrode layer on the substrate; and
patterning the front electrode layer.

4. The method according to claim 1, wherein the first process comprises forming the front electrode patterns on the substrate by a screen printing method, an inkjet printing method, a gravure printing method, or a micro-contact printing method.

5. The method according to claim 1, wherein the first process additionally comprises a texturing process performed to the surface of front electrode patterns.

6. The method according to claim 1, wherein the second process comprises:
forming a semiconductor layer on an entire surface of the substrate; and
patterning the semiconductor layer.

7. The method according to claim 1, wherein the second process comprises:
sequentially forming a semiconductor layer and a transparent conductive layer on an entire surface of the substrate; and
patterning the semiconductor layer and the transparent conductive layer.

8. The method according to claim 2, wherein the second process comprises:
forming a second isolating part in the outermost semiconductor layer pattern, in order to isolate the outermost portions of the substrate by the first and second isolating parts, wherein the second isolating part corresponds to the first isolating part of the front electrode pattern.

9. The method according to claim 1, wherein the second process comprises forming the semiconductor layer pattern of PIN structure where a P-type semiconductor layer, an intrinsic semiconductor layer, and an N-type semiconductor layer are deposited in sequence.

10. The method according to claim 1, wherein the third process comprises forming the rear electrode pattern by a screen printing method, an inkjet printing method, a gravure printing method, or a micro-contact printing method.

11. The method according to claim 8, wherein the third process comprises:
forming a third isolating part in the outermost rear electrode pattern, in order to isolate the outermost portions of the substrate by the first, second, and third isolating parts, wherein the third isolating part corresponds to the first isolating part of the front electrode pattern.

12. A method for manufacturing a thin film solar cell comprising:
forming a front electrode layer on an entire surface of substrate;
forming a plurality of unit front electrode patterns at predetermined intervals by patterning the front electrode layer, wherein the outermost front electrode pattern is provided with a first isolating part;
forming a semiconductor layer and a transparent conductive layer on the entire surface of substrate, sequentially;
patterning the semiconductor layer and the transparent conductive layer, so as to form a separating part to divide the solar cell into unit cells, a contact part to electrically connect the electrode patterns, and a second isolating part corresponding to the first isolating part of the front electrode pattern; and
forming a plurality of unit rear electrode patterns which are provided with a third isolating part corresponding to the first isolating part of the front electrode pattern, are respectively connected with the unit front electrode patterns through the contact part, and are separated from one another by the separating part.

13. The method according to claim 12, wherein forming the unit rear electrode pattern is performed by a screen printing method, an inkjet printing method, a gravure printing method, or a micro-contact printing method.

14. A thin film type solar cell comprising:
a plurality of unit front electrode patterns at predetermined intervals on a substrate;
a semiconductor layer pattern on the substrate, wherein the semiconductor layer pattern is provided with a separating part to divide the solar cell into unit cells, and a contact part to electrically connect the electrode patterns;
a transparent conductive layer pattern above the semiconductor layer pattern, wherein the transparent conductive layer pattern is formed in the same pattern as the semiconductor layer pattern; and
a plurality of unit rear electrode patterns which are respectively connected with the unit front electrode patterns through the contact part, and are separated from one another by the separating part.

15. The thin film type solar cell according to claim 14, wherein a first isolating part is formed in the outermost unit front electrode pattern.

16. The thin film type solar cell according to claim 15, wherein the semiconductor layer pattern includes a second isolating part formed at a portion corresponding to the first isolating part of the front electrode pattern, in which the second isolating part is formed by removing the semiconductor layer; and the rear electrode pattern includes a third isolating part formed at a portion corresponding to the first isolating part of the front electrode pattern, in which the third isolating part is formed by removing the rear electrode.

17. The thin film type solar cell according to claim 14, wherein the semiconductor layer pattern is formed in a PIN structure where a P-type semiconductor layer, an intrinsic semiconductor layer, and an N-type semiconductor layer are deposited in sequence.
